(19) United States
(12) Patent Application Publication
(10) Pub. No.: US 2009/0302403 A1
(43) Pub. Date: Dec. 10, 2009

(54) SPIN TORQUE TRANSFER MAGNETIC MEMORY CELL

(76) Inventor: Paul P. Nguyen, San Jose, CA (US)

Correspondence Address: JOSEPH P. CURTIN, 1469 N.W. MORGAN LANE, PORTLAND, OR, 97229, US

(21) Appl. No.: 12/176,295

(22) Filed: Jul. 18, 2008

Related U.S. Application Data
(60) Provisional application No. 61/059,259, filed on Jun. 5, 2008.

(51) Int. Cl. H01L 29/82

(52) U.S. Cl. 257/421; 257/E29.323

(57) ABSTRACT

A spin-torque magnetic memory element comprises a large magnetic volume, and a thick magnetic layer. The magnetic layer comprises a nearly round shape, a small intrinsic anisotropy and a uniaxial anisotropy that is substantially based on the shape. In one exemplary embodiment, the nearly round shape substantially comprises about a 60 nm by about a 40 nm ellipse shape, and the thick magnetic layer comprises a thickness of about 20 nm to about 100 nm, preferably about 40 nm. In another exemplary embodiment, the thick magnetic layer comprises a first layer of magnetic material that comprises a reasonably high unaxial magnetic anisotropy; and a second layer of magnetic material comprises between about no anisotropy (i.e., 0 anisotropy) and a much lower unaxial magnetic anisotropy than the first layer of magnetic material.

### CROSS-REFERENCE TO RELATED PATENT APPLICATION

The present patent application is related to and claims priority to U.S. Provisional Patent Application 61/059,259, entitled “Spin-Torque Transfer Magnetic Memory Cell Having Low Anisotropy and High Magnetic Moment,” invented by Paul P. Nguyen, and filed Jun. 5, 2008, the disclosure of which is incorporated by reference herein.

### BACKGROUND

The subject matter disclosed herein relates to magnetic memory systems. More particularly, the subject matter disclosed herein relates to a technique for providing a magnetic storage cell having a low anisotropy that that holds the magnetic moment of the cell in place at equilibrium so that the cell will provide a memory that will last at least 8-10 years.

In order for an MRAM to have the characteristics of a non-volatile random access memory, the free layer must exhibit thermal stability against random fluctuations so that the orientation of the free layer is changed only when it is controlled to make such a change. The thermal stability can be achieved via the magnetic anisotropy using different methods, for example, varying the bit size, shape, and crystalline anisotropy. Additional anisotropy can be obtained through magnetic coupling to other magnetic layers either through exchange or magnetic fields. Generally, the anisotropy causes a soft and hard axis to form in thin magnetic layers. The hard and soft axes are defined by the magnitude of the external energy, usually in the form of a magnetic field, needed to fully rotate (saturate) the direction of the magnetization in that direction, with the hard axis requiring a higher saturation magnetic field.

U.S. Pat. No. 6,535,416 B1 to Daughton et al. discloses a conventional MRAM cell structure that has a width and length of 0.1 μm and 0.4 μm respectively. Another exemplary conventional MRAM cell structure disclosed by Daughton et al. has a pinned layer that is 150 Å thick, a ferromagnetic layer that is 40 Å thick, and a ferromagnetic layer that is 150 Å thick. It should be noted that the Daughton et al. cell is relatively large.

U.S. Pat. No. 7,242,048 B2 to Huai discloses a conventional magnetic element is configured such that the free layer can be written using spin transfer. Consequently, the lateral dimensions of at least the free layer and preferably the magnetic element are small—in the range of few hundred nanometers. In one exemplary embodiment, the dimensions of the magnetic element are less than two-hundred nanometers and preferably approximately one-hundred nanometers. The magnetic element preferably has a depth of approximately 50 nm. The depth is preferably smaller than the width w of the magnetic element so that the magnetic element has some shape anisotropy, ensuring that the free layer has a preferred direction. Additionally, the thickness of the free layer is small enough that the spin transfer is strong enough to rotate the free layer magnetization into and out of alignment with the magnetization of the pinned layer. In one exemplary embodiment, the free layer has a thickness of less than five nm.

U.S. Patent Application Publication 2007/0067236 A1 to Huai et al. discloses one known technique for increasing the thermal stability of an MTJ cell that utilizes the shape anisotropy of the magnetic recording layer of a magnetic cell to spatially favor a particular magnetization direction. In some cases, large shape anisotropy may be used to compensate for the insufficient amount of intrinsic crystalline anisotropy that may be, for example, from several to tens of Oersted in terms of an anisotropy field. Based on a static-magnetic model, the switching field for an elliptically shaped MTJ cell can be expressed for the films having in-plane dominant anisotropy as H_{Keff}=H_{Kins}+H_{Kshape} in which H_{Kins} represents the anisotropy field due to crystalline anisotropy and H_{Kshape} represents the anisotropy field due to the shape anisotropy. Notably, H_{Kshape} is proportional to At_{F}/L₁ in which A is the aspect ratio of the MTJ in a plane parallel to the MTJ layers, L₁ is the length along the long axis of the magnetic cell, and t_{F} is the thickness of the free layer. The aspect ratio A should be larger than one, in order to maintain a sufficiently large H_{Kshape} and thus a large effective anisotropy H_{Keff} to meet the thermal stability requirements imposed on the cells. The large anisotropy corresponds to a large thermal activation factor of (KᵤV/k_{B}T), in which Kᵤ is the uniaxial anisotropy energy and V is the volume of the free layer.

The scaling of the magnetic cell embedded into CMOS manufacturing process, however, may impose limitations to the size, geometry and aspect ratio A of the cell. For example, the 130 nm-node CMOS technology can limit the upper limit of the aspect ratio A of the MTJ cells to about 1.77 if the overlap rule is ignored and to around 1 if the overlap rule is taken into account for designing a via size of 0.23 μm with an overlap of 0.055 μm per side. When the more advanced technology node of 90 nm is used, the aspect ratio A of the MTJ cells is actually reduced to 1 from 1.67 for a via size of 0.15 μm with an overlap of 0.03 μm per side. Therefore, due to the CMOS fabrication limitations to the aspect ratio A of each cell, it may be difficult to achieve both a large aspect ratio A and a high cell density at the same time. As such, the approach to stabilizing a MTJ cell based on the shape anisotropy is difficult to implement in memory devices with high areal cell densities. Additionally, cells with asymmetric shapes may increase the process complexity during fabrication and the uniformity of the cells may be difficult to control.

FIG. 1 shows one example of a conventional MTJ cell design 200 that is disclosed by U.S. Patent Application Publication 2007/0067236 A1 to Huai et al. MTJ cell design 200 has a free ferromagnetic layer 202 of high coercivity suitable for achieving a desired level of thermal stability at a low aspect ratio. Free layer 202 is different from the other conventional free layers in that a magnetic biasing layer 201 is formed in contact with and is magnetically coupled to free layer 202 to increase the coercivity of free layer 202. The magnetic coupling between magnetic biasing layer 201 and free layer 202 is set at a level to allow the magnetization direction of free layer 202 to be changeable or switched between two opposite directions by, for example, using a driving current through the MTJ based on the spin-transfer switching. Pinned layer 111 has a fixed magnetization direction which may be along either the first or second direction. An insulator barrier layer 130 is formed between free layer 202 and pinned layer 111 to effectuate tunneling of electrons between free layer 202 and pinned layer 111 under a bias voltage applied between free layer 202 and pinned layer 111 and across insulator barrier layer 130. The metal for forming the insulator barrier layer 130 may be, for example, aluminum (Al), hafnium (Hf), zirconium (Zr), tantalum (Ta) and magnesium (Mg). Additionally, various nitride layers based on different metals may be used to implement the insulator barrier layer 130. Some examples are an aluminum nitride (e.g., AlN), a Ti nitride (e.g., TiN), an AlTi nitride (e.g., TiAlN) and a magnesium nitride. Each of the layers 111, 202 and 114 may have a multilayer structure to include two or more sublayers. The magnetic biasing layer 201 may be antiferromagnetic or ferrimagnetic.

For MTJ cell design 200, ferromagnetic layer 111 is in contact with an antiferromagnetic (AFM) layer 113 and is magnetically coupled to AFM layer 113. Ferromagnetic layer 111 is not “free” and cannot be switched because its magnetization direction is fixed by AFM layer 113. AFM layer 113 is specifically designed to pin the magnetization direction of ferromagnetic layer 111. In this context, AFM layer 113 may be characterized by three parameters: its layer thickness t_{AF}, its anisotropy constant K_{AF} and its interface exchange coupling constant Jᵢₙₜ with the ferromagnetic layer 111. When these parameters for AFM layer 113 meet the condition of K_{AF}t_{AF}>Jᵢₙₜ, the magnetic anisotropy of AFM layer 113 dominates and AFM layer 113 magnetically controls the anisotropy of layer 111 via the magnetic coupling between layers 113 and 111. Under this condition, the magnetization direction of ferromagnetic layer 111 is fixed by the unidirectional anisotropy of AFM layer 113. This pinning condition may be achieved by, for example, using a large AFM layer thickness t_{AF}, an AFM material with a large anisotropy constant K_{AF}, or both large t_{AF} and large K_{AF}. The pinning condition can be achieved with an AFM material that has a large AFM layer thickness t_{AF}, but a relatively small K_{AF}.

Magnetic biasing layer 201 is designed to be magnetically different from AFM layer 113 for pinning layer 111 and for providing a different function from AFM layer 113. Although layer 201 and free layer 202 are magnetically coupled to each other, free layer 202 is still “free” and its magnetization direction can be changed by the driving current based on the spin-transfer switching. As such, biasing layer 201 is designed to meet the following condition: K_{AF}t_{AF}<Jᵢₙₜ. When the thickness of magnetic biasing layer 201 is set to be small, the exchange bias field can be negligibly small, but the coercivity increases with the AFM layer thickness due to the increase of the total anisotropy energy in the free layer 202. Hence, magnetic biasing layer 201 is designed to provide a large anisotropy field for free layer 202. In various implementations, the AFM material for magnetic biasing layer 201 is selected to have a blocking temperature higher than the operating temperatures of the MTJ cell, a large interface exchange coupling constant Jᵢₙₜ, and an appropriately large anisotropy constant K_{AF}. For antiferromagnetic materials, the Neel temperature is the blocking material. For a ferrimagnetic material, its Curie temperature is the blocking temperature. In many applications, the thickness t_{AF} of magnetic biasing layer 201 may be set at a fixed value or changeable. The other two parameters K_{AF} and Jᵢₙₜ are, therefore, adjusted and selected to achieve the condition of K_{AF}t_{AF}<Jᵢₙₜ so that the anisotropic field or coercivity Hc in free layer 202 is sufficient to match the requirement of the thermal stability for the magnetic cell design.

For fixed values of Jᵢₙₜ and K_{AF}, the critical AFM thickness is t_{AFcritical}=Jᵢₙₜ/K_{AF} and is used as an indicator of set-on of the exchange bias field Hex between the two operating regimes. For two widely used AFM materials, IrMn and PtMn, the estimated values for t_{AFcritical} are 40 and 80 Å, respectively with Jᵢₙₜ=0.04(IrMn) and 0.08(PtMn) erg/cm² and K_{AF}=1×10⁺⁵ erg/cm³. In actual device implementations, the values may vary from the above estimates due to various complexities in fabrication processes.

Magnetic biasing layer 201 is designed to be within the regime of K_{AF}t_{AF}<Jᵢₙₜ to deliver a sufficiently large coercivity for the adjacent free layer 202. As an example, for a magnetic cell design with KᵤV/k_{B}T=55 which may be required for data retention for 10 years, the corresponding coercivity in the free layer is about 100 Oe when an IrMn AFM layer is used as the magnetic biasing layer for Area=0.02 μm², t_{F}=25 Å, Ms=1050 emu/cc, and A=1:1. The existing experimental data suggest, however, that most noticeable Hc will be within tens of Oersted and that Hc usually also increases with the exchange bias field Hex. In such a circumstance, the use of the magnetic biasing layer with the free layer to enhance the anisotropy of the latter may necessitate an AFM stack structure and process engineering to suppress the Hex but enhance coercivity within the regime of K_{AF}t_{AF}<Jᵢₙₜ.

When and aspect ratio of MTJ cells are reduced to below a dimension of 200 nm or under 100 nm, such small MTJ cells tend to be thermally unstable and subject to the edge effect of the magnetic domain structure and astray field influence. The edge effect tends to reorient the spin states by causing spin curling up or creating spin vortex states. The reorientation of spin can degrade the magnetic performance of magnetic cells and increase the data error rate in information storage. The use of the magnetic biasing layer may be used to address these issues in various implementations so that the spins align along the easy axis of the magnetic biasing layer due to anisotropic energy interaction between the magnetic biasing layer and free layer, improving the magnetic performance of the magnetic cells.

Notably, the enhanced coercivity in the free layer due to the magnetic interaction with the magnetic biasing layer allows an MTJ cell to achieve a desired level of stability against thermal fluctuations and astray magnetic fields without relying on the shape anisotropy of the cell. As such, if the degree of the cell shape anisotropy is limited, such as when the cells are fabricated with CMOS processing with a dimension around 100 nm, the use of the magnetic biasing layer allows the MTJ cells to be designed and fabricated to comply with the aspect ratios imposed by the CMOS processing techniques. In this context, the geometry or aspect ratio of magnetic cells is no longer a limiting factor to the MTJ cells. Therefore, the use of the magnetic biasing layer can facilitate the cell design and layout. In addition, the coercivity of the free layer can be set to a desired amount by tuning the anisotropy of the magnetic biasing layer via structure and process control. This tuning can be achieved with relative ease and with improved uniformity and process margin in comparison to controlling of the aspect ratio of each cell in CMOS processing.

### BRIEF DESCRIPTION OF THE DRAWING

The subject matter disclosed herein is illustrated by way of example and not by limitation in the accompanying figure in which:

FIG. 1 shows one example of a conventional MTJ cell design that is disclosed by U.S. Patent Application Publication 2007/0067236 A1 to Huai et al.

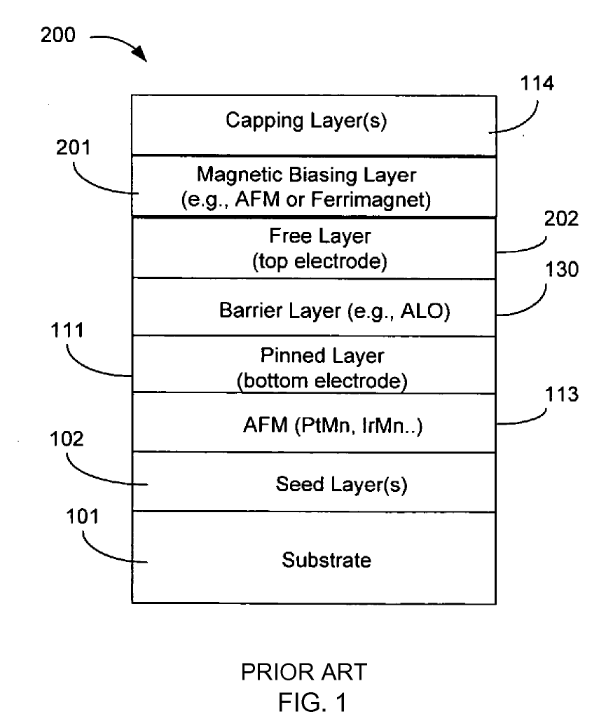

### DETAILED DESCRIPTION

One significant issue with spin torque transfer memory is that the writing current density is still too large. The writing current density can theoretically be reduced significantly by reducing or eliminating the out-of-plane shape anisotropy. According to the subject matter disclosed herein, the out-of-plane shape anisotropy can be reduced or eliminated by increasing the thickness, preferably to around the shorter in-plane dimension of the free magnetic layer, while accordingly reducing the uniaxial magnetic anisotropy of the free magnetic layer of a spin torque transfer memory cell. The reduction ofthe uniaxial magnetic anisotropy should be such that the thermal stability ofthe free magnetic layer is maintained, so that the memory cell can meet whatever the required memory retention time is, usually 8-10 years.

In one embodiment, the free magnetic layer has an in-plane shape of an ellipse, with its unaxial magnetic anisotropy arising substantially from only its shape, only its intrinsic anisotropy, or both its shape and intrinsic anisotropies. To reduce or eliminate the out-of-plane shape anisotropy the thickness of the “thick” free magnetic layer should then be around the thickness value ofthe short axis ofthe ellipse, or between the thickness values of the short and long axes ofthe ellipse. Furthermore, to keep the spin torque critical switching current low, the uniaxial anisotropy coming from shape, intrinsic, or both should also be reduced, but just enough so that adequate thermal stability is still maintained (for instance, with memory retention of 8-10 years). For example, the ellipse's minor and major axes can be 40 nm and 60 nm with minimal or some unaxial intrinsic anisotropy, then the free magnetic layer should be between 20 nm and 100 nm thick, preferably about 40 nm. In contrast, a conventional 60 nm×40 nm ellipse magnetic cell has a free magnetic layer having a thickness of ˜5-20 nm.

In another embodiment, the free magnetic layer has an in-plane shape of a circle, i.e., an ellipse with equal short and long axes. In this case, the unaxial shape anisotropy is zero and the total unaxial shape anisotropy must come from only the intrinsic anisotropy, whose value is chosen to produce a small spin torque critical switching current while maintaining adequate thermal stability. To also reduce or eliminate the out-of-plane shape anisotropy the thickness ofthe “thick” free magnetic layer should be around the thickness of the diameter of the circle. For example, the circle's diameter can be 45 nm and the thickness should be between about 20 nm and about 100 nm, preferably about 45 nm.

Another exemplary embodiment of the subject matter disclosed herein comprises a free magnetic layer formed from a first layer of magnetic material, such as CoFe or NiFe, that is between about 1 nm to about 40 nm thick and that has a reasonably high unaxial magnetic anisotropy, and a second layer of magnetic material that has between about no unaxial magnetic anisotropy (i.e., 0 anisotropy) and a much lower unaxial magnetic anisotropy than the first layer of magnetic material. The unaxial magnetic anisotropy ofthe first layer can be substantially intrinsic, shape, or both, preferably substantially intrinsic. The unaxial magnetic anisotropy of the second layer can be substantially intrinsic, shape, or both, preferably substantially intrinsic and very low. The thickness of the second layer is sufficiently large so that the combined free magnetic layer has a minimum out-of-plane magnetic anisotropy, preferably as close to zero as possible. In one exemplary embodiment, the second magnetic layer comprises a thickness of between about 10 nm and about 100 nm. U.S. Pat. No. 7,242,045 B2 to Nguyen et al., which is incorporated by reference herein, discloses a number of low-saturation magnetization materials that are suitable for both the first and second layers of the free magnetic layer. In one exemplary embodiment, the first and second layers comprise substantially the same magnetic material. In another exemplary embodiment, the first layer comprises a magnetic material that provides a strong read signal. In yet another exemplary embodiment, the first and second layers are formed from at least one low-magnetization material. There can also be more than two layers of different materials for the free magnetic layer. In one exemplary embodiment, both the first layer and the second layer are formed to have substantially no in-plane shape anisotropy, that is, they are formed to be substantially circular. In another exemplary embodiment, both the first layer and the second layer can be formed to have some shape anisotropy to help with the intrinsic anisotropy. The in-plane intrinsic anisotropy of the first thin layer of magnetic material can be set during or after film deposition in an applied magnetic field with or without heating. Alternatively, the intrinsic or crystalline anisotropy ofthe combined layers can be set in an applied magnetic field with or without heating during or after film deposition.

Low magnetization materials may be used to enhance the effect provided by the subject matter disclosed herein, although low magnetization materials are not critically required. The reduction ofthe out-of-plane anisotropy via thick free magnetic layer can also be helped by the use of magnetic materials that have intrinsic perpendicular anisotropy which is perpendicular to the plane of the free magnetic layer.

Although the foregoing disclosed subject matter has been described in some detail for purposes of clarity of understanding, it will be apparent that certain changes and modifications may be practiced that are within the scope of the appended claims. Accordingly, the present embodiments are to be considered as illustrative and not restrictive, and the subject matter disclosed herein is not to be limited to the details given herein, but may be modified within the scope and equivalents of the appended claims.

What is claimed is:

1. A spin-torque magnetic memory element, comprising a thick free magnetic layer.

2. The spin-torque magnetic memory element according to claim 1, wherein the free magnetic layer comprises a nearly round shape, a small intrinsic anisotropy and a uniaxial anisotropy that is based substantially on shape.

3. The spin-torque magnetic memory element according to claim 1, wherein the free magnetic layer comprises a round or nearly round shape, and a sufficient amount of an intrinsic anisotropy to result in a uniaxial anisotropy based substantially on at least one of the intrinsic anisotropy and the intrinsic plus shape anisotropy.

4. The spin-torque magnetic memory element according to claim 1, wherein the thick magnetic layer comprises:
a first layer of magnetic material that comprises a reasonably high unaxial magnetic anisotropy; and
a second layer of magnetic material comprises between about no unaxial anisotropy and a much lower unaxial magnetic anisotropy than the first layer of magnetic material.

5. The spin-torque magnetic memory element according to claim 4, wherein the first layer and the second layer comprise substantially the same magnetic material.

6. The spin-torque magnetic memory element according to claim 4, wherein the first layer comprises a magnetic material that provides a strong read signal.

7. The spin-torque magnetic memory element according to claim 4, wherein the first and second layers are formed from at least one low-magnetization material.

8. The spin-torque magnetic memory element according to claim 4, wherein the first layer of magnetic material is between about 1 nm to about 40 nm thick.

9. The spin-torque magnetic memory element according to claim 8, wherein the first layer of magnetic material is formed from at least one of CoFe and NiFe.

10. The spin-torque magnetic memory element according to claim 4, wherein the second layer of magnetic material is between about 10 nm to about 100 nm thick.

11. The spin-torque magnetic memory element according to claim 4, wherein the second layer of the magnetic material comprises a thickness so that the combined first and second layers have a minimal out-of-plane magnetic shape anisotropy.

12. The spin-torque magnetic memory element according to claim 11, wherein the combined first and second layers comprise substantially a zero out-of-plane magnetic anisotropy.

13. The spin-torque magnetic element according to claim 4, wherein the first layer and the second layer are formed to comprise substantially no unaxial shape anisotropy.

14. The spin-torque magnetic element according to claim 4, wherein the first layer and the second layer are formed to comprise a small amount of unaxial anisotropy, wherein the unaxial anisotropy is between zero and the value of shape anisotropy of a thin-film ellipse having a major axis that is twice as long as a minor axis of the ellipse.

15. The spin-torque magnetic memory element according to claim 4, wherein the spin-torque magnetic memory element is part of an array of spin-torque magnetic memory elements.

16. The spin-torque magnetic memory element according to claim 15, wherein the array of spin-torque magnetic memory elements comprises a plurality of spin-torque magnetic memory elements each comprising at least one of a thick magnetic layer.

17. The spin-torque magnetic memory element according to claim 1, further comprising a critical switching current density magnitude that is reduced from a magnitude of a critical switching current density for a conventional spin-torque magnetic memory element.

18. The spin-torque magnetic memory element according to claim 1, wherein the spin-torque magnetic memory element is formed from at least one low-magnetization material.

19. The spin-torque magnetic memory element according to claim 1, wherein the spin-torque magnetic memory comprises about a 60 nm by about a 40 nm ellipse shape, and wherein the thick magnetic layer comprises a thickness of about 20 nm to about 100 nm.

20. The spin-torque magnetic memory element according to claim 19, wherein the thick magnetic layer comprises a reduced out-of-plane anisotropy and an uniaxial anisotropy that is less than or about the same as a magnetic layer of a conventional a magnetic layer comprising a thickness of about 1 nm to about 20 nm.

21. The spin-torque magnetic memory element according to claim 20, further comprising a critical switching current density magnitude that is reduced from a magnitude of a critical switching current density for a conventional spin-torque magnetic memory element.

22. The spin-torque magnetic memory element according to claim 20, wherein the spin-torque magnetic memory element is formed from at least one low-magnetization material.

23. The spin-torque magnetic memory element according to claim 20, wherein the spin-torque magnetic memory element is part of an array of spin-torque magnetic memory elements.

24. The spin-torque magnetic memory element according to claim 23, wherein the array of spin-torque magnetic memory elements comprises at least one spin-torque magnetic memory element comprising a thick magnetic layer.

25. The spin-torque magnetic memory element according to claim 24, wherein at least one of the spin-torque magnetic memory elements further comprises a free magnetic layer comprising a nearly round shape, a small intrinsic anisotropy and a uniaxial anisotropy that is based substantially on the shape.

26. The spin-torque magnetic memory element according to claim 24, wherein at least one of the spin-torque magnetic memory elements further comprises a free magnetic layer comprising a round or nearly round shape, and a sufficient amount of an intrinsic anisotropy to result in a uniaxial anisotropy based substantially on at least one of the intrinsic anisotropy and the intrinsic plus shape anisotropy.

27. The spin-torque magnetic memory element according to claim 24, wherein the nearly round shape of at least one of the spin-torque magnetic memory elements substantially comprises about a 60 nm by about a 40 nm ellipse shape, and
wherein the thick magnetic layer of the spin-torque magnetic memory element comprises a thickness of about 20 nm to about 100 nm.

28. The spin-torque magnetic memory element according to claim 27, wherein the thick magnetic layer of at least one of the of spin-torque magnetic memory cells comprises a reduced out-of-plane magnetic anisotropy and an uniaxial anisotropy that is less than or about the same as a magnetic layer of a conventional a magnetic layer comprising a thickness of about 1 nm to about 20 nm.

29. The spin-torque magnetic memory element according to claim 28, wherein at least one of the spin-torque magnetic memory elements further comprises a critical switching current density magnitude that is reduced from a magnitude of a critical switching current density for a conventional spin-torque magnetic memory element.

30. The spin-torque magnetic memory element according to claim 28, wherein at least one of the spin-torque magnetic memory elements is formed from at least one low-magnetization material.
